(19) United States
(12) Patent Application Publication
(10) Pub. No.: US 2022/0209100 A1
(43) Pub. Date: Jun. 30, 2022

(54) METHOD OF PREPARING A SOLID SOLUTION CERAMIC MATERIAL HAVING INCREASED ELECTROMECHANICAL STRAIN, AND CERAMIC MATERIALS OBTAINABLE THEREFROM

(71) Applicant: Xaar Technology Limited, Huntingdon, Cambridgeshire (GB)

(72) Inventors: David CANN, Corvallis, OR (US); Brady GIBBONS, Corvallis, OR (US); Peter MARDILOVICH, Huntingdon, Cambridgeshire (GB)

(21) Appl. No.: 17/612,075

(22) PCT Filed: May 22, 2020
(86) PCT No.: PCT/GB2020/051251

§ 371 Date: Nov. 17, 2021

(30) Foreign Application Priority Data
May 22, 2019 (GB) 1907238.8

(51) Int. Cl. H01L 41/43; C04B 35/49; C04B 35/64; H01L 41/187; B41J 2/14

(52) U.S. Cl. CPC H01L 41/43; C04B 35/49; C04B 35/64; H01L 41/1871; B41J 2/14201; C04B 2235/762; C04B 2235/3248; C04B 2235/768; C04B 2235/767; C04B 2235/765; C04B 2235/766; C04B 2235/3234

(57) ABSTRACT

The present invention relates to a method of preparing a solid solution ceramic material having increased electromechanical strain, as well as ceramic materials obtainable therefrom and uses thereof. In one aspect, the present invention provides a method A method of increasing electromechanical strain in a solid solution ceramic material which exhibits an electric field induced strain derived from a reversible transition from a non-polar state to a polar state; i) determining a molar ratio of at least one polar perovskite compound having a polar crystallographic point group to at least one non-polar perovskite compound having a non-polar crystallographic point group which, when combined to form a solid solution, forms a ceramic material with a major portion of a non-polar state; ii) determining the maximum polarization, Pₘₐₓ, remanent polarisation, Pᵣ, and the difference, Pₘₐₓ−Pᵣ, for the solid solution formed in step i); and either: iii)a) modifying the molar ratio determined in step i) to form a different solid solution of the same perovskite compounds which exhibits an electric field induced strain and which has a greater difference, Pₘₐₓ−Pᵣ, between maximum polarization, Pₘₐₓ, and remanent polarisation, Pᵣ, than for the solid solution from step i), or; iii)b) adjusting the processing conditions used for preparing the solid solution formed in step i) to increase the difference, Pₘₐₓ−Pᵣ, in maximum polarization, Pₘₐₓ, and remanent polarisation, Pᵣ, of the solid solution.

The present invention relates to a method of preparing a solid solution ceramic material, capable of reversible deformation upon electric field application, through the relaxor-ferroelectric crossover mechanism, with improved d₃₃*. The present invention also relates to the ceramic material obtainable therefrom and uses thereof. In particular, the present invention relates to a method of preparing a ceramic material which is particularly useful in an actuator component of a droplet ejection apparatus.

Actuator materials are needed to generate electric-field induced strains for a wealth of devices including, for instance, mechanical relays, digital cameras, and ink-jet printers. The composition and crystal structure of the actuator material are critical to determining the actuator characteristics. Common actuator materials include piezoelectric materials which undergo physical changes in shape when exposed to an external electric field. However, dielectric materials that do not exhibit the piezoelectric effect may also potentially find application as actuators.

In principle, all dielectric materials exhibit electrostriction, which is characterised by a change in shape under the application of an electric field. Electrostriction is caused by displacement of ions in the crystal lattice upon exposure to an external electric field; positive ions being displaced in the direction of the field and negative ions displaced in the opposite direction. This displacement accumulates throughout the bulk material and results in an overall macroscopic strain (elongation) in the direction of the field. Thus, upon application of an external electric field, the thickness of a dielectric material will be reduced in the orthogonal directions characterized by Poisson's ratio. Electrostriction is known to be a quadratic effect, in contrast to the related effect of piezoelectricity, which is primarily a linear effect observed only in a certain class of dielectrics.

The critical performance characteristics for an actuator material include the effective piezoelectric coefficient, d₃₃*, the temperature dependence of d₃₃* and the long-term stability of d₃₃* in device operation. Lead zirconate titanate (PZT), Pb(ZrₓTi₁₋ₓ)O₃, and its related solid solutions, are a well-known class of ceramic perovskite piezoelectric materials that have found use in a wide variety of applications utilising piezoelectric actuation. However, as a result of emerging environmental regulations, there has been a drive to develop new lead-free and lead-lean actuator materials.

Significant attention has been given to electric field induced strain behaviour of alternative lead-free dielectric materials for potential actuator applications, examples of which include (K,Na)NbO₃-based materials, (Ba,Ca)(Zr,Ti)O₃-based materials and (Bi,Na,K)TiO₃-based materials. Ceramics with the perovskite structure have been of particular interest in this regard. The perovskite structure is unique in that constituent ions within the unit cell are easily displaced giving rise to various ferroelectrically-active non-cubic perovskite phases such as those with tetragonal, rhombohedral, orthorhombic or monoclinic symmetry. The relatively large tolerance for substitutional atoms in the perovskite structure is beneficial for chemical modifications, enabling functional properties to be tailored. When an external electric field is applied, these perovskite-structured ceramics are deformed along with the changes in their macroscopic polarisation state.

The perovskite compound bismuth sodium titanate (Bi_{0.5}Na_{0.5})TiO₃ (“BNT”) has, in particular, been studied extensively in the pursuit of lead-free actuator materials, including solid solutions comprising BNT with other components intended to enhance BNT's dielectric and piezoelectric properties. WO 2012/044313 and WO 2012/044309 describe a series of lead-free piezoelectric materials based on ternary compositions of BNT and (Bi_{0.5}K_{0.5}) TiO₃ (“BKT”) in combination with (Bi_{0.5}Zn_{0.5})TiO₃ (“BZT”), (Bi_{0.5}Ni_{0.5})TiO₃ (“BNiT”), or (Bi_{0.5}Mg_{0.5})TiO₃ (“BMgT”). WO 2014/116244 also describes ternary compositions of BiCoO₃ together with perovskites such as BaTiO₃ (“BT”), (Na,K)NbO₃ (“KNN”), BNT and BKT.

Perovskite ceramic materials which exhibit giant electrostrains have become a growing focus for potential actuator applications. A giant electric-field induced strain was, for example, found in the case of the BNT-BT-KNN perovskite ceramic system which was considered a particularly interesting discovery in the pursuit of lead-free ceramics which may compete with PZT in actuator applications. There has been speculation that desirable giant electrostrains, such as that exhibited by BNT-BT-KNN, may be attributed to a reversible phase transformation from a disordered ergodic (non-polar) relaxor state to a long-range non-ergodic (polar) ferroelectric ordered state in certain perovskite ceramics driven by an external electric field, as discussed in J Electroceram (2012) 29: 71-93. The characteristics of the giant strain in the BNT-BT-KNN perovskite ceramic system are, for instance, illustrated by composition dependent strain hysteresis loops in FIG. 9 of J Electroceram (2012) 29: 71-93.

In J Electroceram (2012) 29: 71-93 it is indicated that the giant electrostrains exhibited via the piezoelectric effect are the result of a strain-generating phase transition and that such a phenomenon extends the opportunities for actuator applications in a new manner. Furthermore, it is also said that BNT-based systems exhibiting giant electric-field-induced strains have the potential to replace PZT in the realm of actuator applications provided that certain challenges can be overcome, such as relatively large driving electric fields and frequency dependence, as well as temperature instability.

Bai et al., Dalton Trans., 2016, 45, 8573-8586, describe a lead-free BNT-BT-BZT (where BZT is Bi(Zn_{0.5}Ti_{0.5})O₃) ceramic system and how the addition of BZT to a solid solution of BNT-BT has a strong impact on the phase transition characteristics and electromechanical properties, as confirmed by X-ray diffraction (XRD) measurements, Raman spectra analysis and temperature-dependent changes in polarisation and strain hysteresis loops. Bai et al. describe that the addition of BZT “disrupts” the ferroelectric order to create a “non-polar” state at zero electric field. On the application of an electric field, the BNT-BT-BZT ceramic material transitions from a pseudo-cubic mixture of tetragonal and rhombohedral structures to a purely rhombohedral phase.

The present invention aims at preparing a family of alternative lead-free or lead-lean perovskite ceramic materials which exhibit giant electrostrains derived from a phase transition mechanism for use in actuator applications and without the problems associated with large electric field requirements and a frequency dependence and/or temperature instability.

Generally, in order to prepare a ceramic material which exhibits the specific desirable phase transition, the inventors have previously found it necessary to modify a solid solution ceramic material exhibiting a tetragonal phase (“parent phase”) by incorporating one or more additional perovskite compounds (“disorder phase”) into the solid solution. The addition of the disorder phase acts to disrupt the long-range tetragonal order of the parent phase (i.e. the long range electric dipolar order underpinning the tetragonal phase) such that the resulting ceramic material exhibits a pseudo-cubic phase in the absence of an applied electric field. When an electric field is applied to the ceramic material having the pseudo-cubic phase, a giant electrostrain may be observed which derives from a transition from the pseudo-cubic phase to the tetragonal phase associated with the parent phase.

GB2559388 describes a method of identifying a solid solution ceramic material containing at least two or three perovskite compounds which exhibits an electric field induced strain derived from a reversible phase transition. Said method comprises a first step of determining a molar ratio of at least one tetragonal perovskite compound to at least one non-tetragonal perovskite compound which, when combined to form a solid solution, provides a ceramic material comprising a major portion of a tetragonal phase; or selecting a tetragonal perovskite compound suitable for forming a ceramic material comprising a major portion of a tetragonal phase. In both cases, the second step is to determine a molar ratio of at least one additional non-tetragonal perovskite compound to the perovskite compound or combination of perovskite compounds from the first step at the determined molar ratio which, when combined to form a solid solution, provides a ceramic material comprising a major portion of a pseudo-cubic phase.

There still remains the need for new methods for designing solid solution relaxor-ferroelectric crossover materials with optimized electrostrain properties in order to obtain materials that constitute a viable alternative to traditional piezoelectric materials, especially those based on lead zirconate titanate (PZTs), for a wide range of applications including electromechanical actuators.

The present invention focuses on the provision of new materials by accounting for the inherent stability of the polarisation in solid solution ceramic materials. In particular, the present inventors have found that large electromechanical strains in such materials may be obtained through an electric field induced transition from a non-polar state to a polar state.

### SUMMARY

Thus, in a first aspect, the present invention relates to a method of increasing electromechanical strain in a solid solution ceramic material which exhibits an electric field induced strain derived from a reversible transition from a non-polar state to a polar state. Said method includes: i) determining a molar ratio of at least one polar perovskite compound having a polar crystallographic point group to at least one non-polar perovskite compound having a non-polar crystallographic point group which, when combined to form a solid solution, form a ceramic material with a major portion of a non-polar state; ii) determining the maximum polarization Pₘₐₓ, remanent polarisation Pᵣ and the Pₘₐₓ−Pᵣ parameter for the solid solution formed in step i); and either: iii) a) modifying the molar ratio determined in step i) to form a different solid solution of the same perovskite compounds which exhibits an electric field induced strain and which has a greater Pₘₐₓ−Pᵣ parameter between maximum polarization Pₘₐₓ and remanent polarisation Pᵣ than for the solid solution from step i), or; iii) b) adjusting the processing conditions (e.g. temperature, time, atmosphere, oxygen partial pressure) used for preparing the solid solution formed in step i) to increase Pₘₐₓ−Pᵣ parameter in maximum polarization Pₘₐₓ and remanent polarisation Pᵣ of the solid solution.

In a second aspect, the present invention relates to a method of preparing a solid solution ceramic material of at least one polar perovskite compound and at least one non-polar perovskite compounds, wherein the ceramic material comprises a major portion of a non-polar state; said method comprising the steps of: I) mixing precursors for the perovskite compounds of the ceramic material in predetermined molar ratios; wherein the predetermined molar ratios of precursors are determined based on the molar ratio of perovskite compounds in the solid state ceramic material determined in step iii) a) according to the first aspect of the invention; and II) utilising the mixture of precursors formed in step I) in a solid-state synthesis to prepare the solid solution ceramic material. Alternatively, said method comprises the steps of: A) mixing precursors for the perovskite compounds of the ceramic material in predetermined molar ratios; wherein the predetermined molar ratios of precursors are determined based on the molar ratio of perovskite compounds in the solid state ceramic material determined in step i) according to the method of the first aspect of the invention; and B) utilising the mixture of precursors formed in step A) in a solid-state synthesis to prepare the solid solution ceramic material; wherein the processing conditions (e.g. temperature, time, atmosphere, oxygen partial pressure) used to provide an increased Pₘₐₓ−Pᵣ parameter in maximum polarization Pₘₐₓ and remanent polarisation Pᵣ of the solid solution determined in step iii)b) according to the first aspect of the invention are used to prepare the ceramic material.

In a third aspect, the present invention relates to a solid solution ceramic material obtainable, and preferably obtained, from the method of the second aspect.

In a fourth aspect, the present invention relates to a solid solution ceramic material of at least one polar perovskite compound and at least one non-polar perovskite compound as defined in the first aspect, wherein the ceramic material comprises a major portion of a non-polar state; wherein the difference, Pₘₐₓ−Pᵣ, in maximum polarization Pₘₐₓ and remanent polarisation Pᵣ of the ceramic material is greater than 20 μC/cm²; preferably greater than 30 μC/cm².

In a fifth aspect, the present invention relates to an actuator component for use in a droplet ejection apparatus comprising a ceramic material according to the third or fourth aspects.

In a sixth aspect, the present invention relates to a droplet ejection apparatus comprising an actuator component according to the fifth aspect.

### BRIEF DESCRIPTION OF THE DRAWINGS

FIG. 1: XRD patterns for 0.4 BNT-(0.6-x) BKT-x SZ, where x=0.02, 0.025, 0.03, (a) 2θ=20°-60° (b) 2θ=39°-40° and (c) 2θ=45.5°-46.5°;

FIG. 2: (a) polarisation (b) bipolar strain and (c) unipolar strain versus electric field for 0.4 BNT-(0.6-x) BKT-x SZ ceramics where, x=0.02, 0.025, 0.03 measured at 10 Hz and room temperature (25° C.);

FIG. 3: (a) polarisation (b) bipolar strain and (c) unipolar strain versus electric field and d₃₃* value (Sₘₐₓ/Eₘₐₓ, pm/V) for (80-x) BNT-20 BKT-xSZ ceramics where, x=0, 0.01, 0.02, 0.025, 0.05 measured at 10 Hz and room temperature (25° C.);

FIG. 4: P_{max.}−Pᵣ and d₃₃* (Sₘₐₓ/Eₘₐₓ) versus SZ content in (80-x) BNT-20 BKT-x SZ ceramics, where x=0, 0.01, 0.02, 0.025, 0.05;

FIG. 5: (a) Polarization (b) bipolar strain and (c) unipolar strain versus electric field and d₃₃* value (Sₘₐₓ/Eₘₐₓ, pm/V) for (80-x) BNT-20 BKT-x SHZ ceramics, where x=0, 0.02, 0.03, 0.05 measured at 10 Hz and at room temperature (25° C.);

FIG. 6: P_{max.}−Pᵣ and d₃₃* (Sₘₐₓ/Eₘₐₓ) values versus SHZ content for (80-x) BNT-20 BKT-x SHZ ceramics, where x=0, 0.02, 0.03, 0.05;

FIG. 7: (a) polarisation (b) bipolar strain and (c) unipolar strain versus electric field and d₃₃* value (Sₘₐₓ/Eₘₐₓ, pm/V) for 40 BNT-57.5 BKT-2.5 SrZrO₃ ceramics sintered at 1125° C. for different sintering times measured at 10 Hz and room temperature (25° C.);

FIG. 8: P_{max.}−Pᵣ and d₃₃* (Sₘₐₓ/Eₘₐₓ) values versus sintering time for 40 BNT-57.5 BKT-2.5 SZ ceramics; and

FIG. 9: (a) polarisation (b) bipolar strain and (c) unipolar strain versus electric field and d₃₃* value (Sₘₐₓ/Eₘₐₓ, pm/V) for 40 BNT-57.5 BKT-2.5 SZ ceramics prepared with starting solutions having different content in mole fraction of volatile cations (K⁺ or Na⁺)measured at 10 Hz and at room temperature (25° C.).

### DETAILED DESCRIPTION

It has been found by the inventors that a relaxor-ferroelectric crossover material may be provided with improved d₃₃* by maximising the difference between the maximum polarisation, Pₘₐₓ, and the remanent polarisation, Pᵣ. This may be achieved by determining the molar ratio of the components of the solid solution which maximise Pₘₐₓ−Pᵣ and/or suitably adjusting the conditions of the process of preparing said material and/or introducing defects in the material's structure.

Therefore, the method of the present invention is capable of increasing the electromechanical strain in solid solution ceramic materials by modifying polarisation properties. The present inventors have found that large electromechanical strains in such materials may be obtained through an electric field induced transition from a non-polar state to a polar state. The extent of the transition from a non-polar state to a polar state is determined by the stability of the polar regions (as one example, domains) of the solid solution ceramic material.

The absence of stable polarisation in a ceramic material is fundamentally associated with the absence of stable polar regions at zero-field. In that case, polarisation can only be obtained by applying an electric field of sufficient magnitude that causes a reversible transition into a polar state with long range dipole order. The stability of the polarisation of a ceramic material may be quantified as the difference between the maximum electric-field induced polarization, Pₘₐₓ, and the zero-field remanent polarization, Pᵣ. The stability of polarization herein is thus defined by the parameter, Pₘₐₓ−Pᵣ. The larger the difference between Pₘₐₓ and Pᵣ, the less stable the polarisation at zero-field, and the larger the electromechanical strain that may be induced in the material. The inventors have found that the stability of polarization parameter, Pₘₐₓ−Pᵣ, may be controlled by choosing an appropriate composition which causes the destabilization of the remanent polarization in the ceramic material.

The present invention therefore relates to a new approach to providing solid solution ceramic materials exhibiting large electromechanical strain, and one which may be used to further refine and improve existing approaches to identifying such materials. In particular, the present invention may be applied in connection with the crossover mechanism described above. The materials capable of undergoing the crossover mechanism are also inherently sensitive to local structural arrangements, especially those that destabilise the polar state. Thus, further to the disruption of the long-range order in the material structure through the introduction of a “disorder phase” as described above, the present invention can be applied to destabilise the polarisation within the material by modifying the local structure. This can be achieved through compositional modifications of the solid solution ceramic material. In addition, external parameters such temperature, pressure, in-plane stress induced in a thin film via a substrate, and frequency of the applied electric field, may also affect the stability of the polarisation. This means that a device that includes this material can be designed with control over these external parameters so as to obtain the optimum actuator characteristics. Furthermore, in considering the fabrication of said actuator material, it has been shown that the destabilisation of the polarisation may also be induced by choosing suitable process conditions when preparing the material.

It has previously been found to be possible to provide a ceramic material exhibiting giant electrostrain based on a selection of certain perovskite compounds having particular phase characteristics which, when combined to form a solid solution, are capable of electric field induced strains as a result of a phase transition, in particular from a pseudo-cubic phase to a tetragonal phase. This corresponds to a form of the cross-over or “relaxor-to-ferroelectric transition” mechanism discussed above, through which an electric field may be used to induce strain.

The present inventors have now found a new method of increasing electromechanical strain in solid solution ceramic materials and one which may be applied to further enhance the benefits achievable based on the principles underlying the cross-over mechanism.

The method according to the invention is able to provide a ceramic material of enhanced piezoelectric performance, the method including selecting a non-polar relaxor-to-ferroelectric crossover solid solution ceramic starting material with disrupted long range structural order which is capable of an electric field induced transition to a polar state with giant electromechanical strain, and further destabilising the material's short range structural order and, ultimately, its polarisation by modifying its composition, processing conditions and/or by introducing defects in its structure.

Since, as described above, large electromechanical strains are linked to the transition from a non-polar state to a polar state with associated formation of domains with aligned dielectric dipoles, they are dependent on the local structure of the material. The local structure of a material may affect the stability of its polarisation. The aim of the present method is to destabilise the polarisation of the material, in other words to induce a loss of remanent polarisation, by modifying the local structure of the material.

The stability of the polarisation may be quantified in terms of the parameter, Pₘₐₓ−Pᵣ. This parameter is defined on the basis of a polarisation-hysteresis measurement, typically at a frequency of 1-10 Hz for bulk ceramics and 10 Hz to 10 kHz for thin film embodiments. The destabilisation of the polarisation is observed through a decrease in the remanent polarisation, which in turn is linked to an increase of the electric field induced strain.

In order to prepare a ceramic material which exhibits the particular desirable phase transition, it is advantageous to modify a solid solution ceramic material exhibiting a polar state (“parent phase”) by incorporating one or more additional perovskite compounds (“disorder phase”) into the solid solution. The addition of the disorder phase acts to disrupt the long-range dipole order within the parent phase (i.e. the long range electric dipolar order) such that, in the absence of an applied electric field, the resulting ceramic material is in a non-polar state, for example a pseudo-cubic phase. When an electric field is applied to the ceramic material in the non-polar state, a giant electrostrain may be observed which is associated with a transition from the non-polar state back to the polar state, which is associated with the parent phase.

There are different ways of influencing the stability of the polarisation of the above material, and to obtain the desired high performance final material. This can be achieved, and has been experimentally demonstrated, by altering the composition, by adding impurities/defects, or by adjusting processing conditions, such as the sintering conditions (i.e. temperature, time, atmosphere). It is crucial to induce changes in the short range structure of the solid solution ceramic materials and to thereby modify the nature and/or extent of a transition from a non-polar state to a polar state, for instance a transition from a non-ergodic relaxor to ergodic relaxor state, in order to arrive at materials with improved d₃₃*. As the skilled person will appreciate, reference to the effective piezoelectric coefficient (d₃₃*) herein refers to that which is determined from dividing the maximum electromechanical strain (Sₘₐₓ) by the maximum applied electric field (Eₘₐₓ) (d₃₃*=Sₘₐₓ/Eₘₐₓ).

The method of the present invention requires the following steps: i) determining a molar ratio of at least one polar perovskite compound having a polar crystallographic point group to at least one non-polar perovskite compound having a non-polar crystallographic point group which, when combined to form a solid solution, forms a ceramic material with a major portion of a non-polar state; ii) determining the maximum polarization, Pₘₐₓ, remanent polarisation, Pᵣ, and the difference, Pₘₐₓ−Pᵣ, for the solid solution formed in step i); and either: iii) a) modifying the molar ratio determined in step i) to form a different solid solution of the same perovskite compounds which exhibits an electric field induced strain and which has a greater difference, Pₘₐₓ−Pᵣ, between maximum polarization, Pₘₐₓ, and remanent polarisation, Pᵣ, than for the solid solution from step i), or; iii) b) adjusting the processing conditions (principally processing temperature and time, as well as atmosphere and pressure) used for preparing the solid solution formed in step i) to increase the difference, Pₘₐₓ−Pᵣ, in maximum polarization, Pₘₐₓ, and remanent polarisation, Pᵣ, of the solid solution.

Pᵣ and Pₘₐₓ values may be obtained from polarization hysteresis measurements, for example using a Sawyer-Tower circuit or similar. It will be understood that the ceramic material formed through the method of the present invention will have a major portion of a non-polar state in the absence of an applied electric field and a major portion of a polar state in the presence of an applied electric field.

In some embodiments of the invention step i) of the method may include the following sub-steps: i-a) preparing at least one solid solution ceramic material of at least one polar, preferably tetragonal, perovskite compound and at least one non-polar, preferably cubic, perovskite compound in a particular molar ratio; i-b) determining whether the axial ratio c/a and/or rhombohedral angle of the major phase of the at least one solid solution ceramic material prepared in step i-a) corresponds to a pseudo-cubic phase having an axial ratio c/a of from 0.995 to 1.005 and/or a rhombohedral angle of 90±0.2 degrees; and i-c) optionally repeating sub-steps i-a) and i-b) using a different molar ratio of the at least one polar, preferably tetragonal, perovskite compound and the at least one non-polar, preferably cubic, perovskite compound to that of step i-a) until the axial ratio c/a and/or rhombohedral angle of the major phase of the resulting solid solution ceramic material corresponds to a pseudo-cubic phase having an axial ratio c/a of from 0.995 to 1.005 and/or a rhombohedral angle of 90±0.2 degrees.

Solid solution ceramic materials of pseudo-cubic phase having an axial ratio c/a of from 0.995 to 1.005 and/or a rhombohedral angle of 90±0.2 degrees have disrupted long range order and are capable of electric filed induced strain through a transition from a pseudo-cubic phase to a tetragonal phase according to a crossover mechanism.

As the skilled person is aware, the axial ratio c/a is defined based on the lattice parameters of the perovskite unit cell, specifically as the length of crystallographic (001) axis (c) divided by the (100) axis (a). Phase and crystal structure, including the axial ratio c/a of a ceramic material, may be readily identified using X-ray diffraction (XRD) analysis, for instance, employing Cu Kα radiation. The rhombohedral angle may also be derived through refinement of the X-ray diffraction data.

Additionally, step iii) a) of the method may include the following sub-steps: iii)a)-1 preparing at least one solid solution ceramic material comprising the same perovskite compounds of step i) in a different molar ratio; wherein the solid solution prepared has a major portion of a non-polar state; iii)a)-2 determining whether the difference, Pₘₐₓ−Pᵣ, between maximum polarization, Pₘₐₓ, and remanent polarisation, Pᵣ, for the at least one solid solution prepared in sub-step iii)a-1 is greater than that of the solid solution from step i); iii)a-3 optionally repeating sub-steps iii)a)-1 and iii)a)-2 using a different molar ratio of the perovskite compounds to that of step iii)a)-1 until the difference, Pₘₐₓ−Pᵣ, between maximum polarization, Pₘₐₓ, and remanent polarisation, Pᵣ, for the solid solution is greater than that for the solid solution prepared in step i).

Additionally or alternatively, step iii)b) may comprise at least one of 1) changing the calcination and/or sintering temperature of a solid state synthesis; 2) changing the calcination and/or sintering time of a solid state synthesis; and/or 3) changing the cationic excess or deficiency of constituent cations in a solid state synthesis, used in the preparation of the solid solution until the difference, Pₘₐₓ−Pᵣ, between maximum polarization, Pₘₐₓ, and remanent polarisation, Pᵣ, is greater than that for the solid solution prepared in step i).

It is well-known that Bi, Na, K and Pb, which are common constituent cations of ceramic materials, are all volatile species, particularly at the process temperatures necessary for calcination and sintering of perovskite ceramics. To compensate for the high volatility of certain cations, a non-stoichiometric excess of constituent cations may be added as part of the solid state synthesis process.

An appropriate level of cation excess necessary to obtain the desired stoichiometry of the ceramic material may be determined by the skilled person by routine experimentation. If, on the other hand, there is a stoichiometric imbalance, point defects can occur which disrupt the local structure, or short range order, of the ceramic material. This may affect the stability of the polarisation and, therefore, the super-stoichiometric or sub-stoichiometric contents of constituent cations may be found by routine experimentation that suitably destabilise the polarisation of the solid solution ceramic material according to the present invention.

Suitable modifications to the cation stoichiometry for the processing of bulk ceramics may include, for example, the addition of up to 20 mol. % excess Na₂CO₃, K₂CO₃ and Bi₂O₃, and up to 10 mol. % excess PbO or PbCO₃. Compositions may also be modified to include cation deficiencies, including a maximum of 10 mol. % deficient Na₂CO₃, K₂CO₃ and Bi₂O₃, and up to 5 mol. % deficient PbO or PbCO₃. In the processing of thin film embodiments the larger surface-to-volume ratio requires greater levels of non-stoichiometry, thus greater levels of non-stoichiometry are required. For example, the addition of up to 30 mol. % excess Na-, K-, and Bi-precursors, and up to 25 mol. % excess of Pb-precursors.

In some embodiments, in step i) the solid solution is prepared by a solid state synthesis using the appropriate amounts of precursors starting powders of at least 99% purity. In general, conventional solid state synthesis methods for making ceramic materials involve milling of the powder precursors, followed by shaping and calcining to produce the desired ceramic product. Milling can be either wet or dry type milling. High energy vibratory milling may be used, for instance, to mix starting powders, as well as for post-calcination grinding. Where wet milling is employed, the powders are mixed with a suitable liquid (e.g., ethanol or water, or combinations thereof) and wet milled with a suitable high density milling media (e.g., yttria stabilized zirconia (YSZ) beads). The milled powders are then calcined.

The calcined powder is then mixed with a binder, formed into the desired shape (e.g., pellets) and sintered to produce a ceramic product with high sintered density. In some embodiments of the invention, the sintering step may last from 1 to 12 hours and step iii)b) may comprise increasing the sintering time by from 50 to 1000%, or from 100 to 500%, or from 200 to 400%.

In some embodiments, the sintering step may be performed at a temperature from 900 to 1400° C. and step iii)b) may comprise increasing the sintering temperature by 5 to 25%, or from 10 to 20%, or from 10 to 15%.

In preferred embodiments, the sintering step may be performed at a temperature from 1000 to 1125° C. Additionally the sintering step may last 2 to 6 hours.

For testing purposes, prior to electrical measurements, the ceramic disc may be polished to a suitable thickness (e.g., 0.9 mm), and a silver paste (e.g., Heraeus C1000) is applied to both sides of the discs. Depending upon the intended end use, a high-density ceramic disc or pellet may be polished to a thickness in the range of about 0.5 pm to about 1 pm.

In some embodiments the solid solution prepared according to the method of the present invention may comprise a single polar perovskite compound and/or a plurality of non-polar perovskite compounds. In preferred embodiments the solid solution comprises two non-polar perovskite compounds.

The at least one polar perovskite compound may be selected from compounds with a crystallographic point group selected from 6 mm (hexagonal), 6 (hexagonal), 4 mm (tetragonal), 4 (tetragonal), 3 m (trigonal), 3 (trigonal), mm2 (orthorhombic), 2 (monoclinic), m (monoclinic), and 1 (triclinic), preferably wherein the at least one polar perovskite compound is selected from compounds with a crystallographic point group selected from 4 mm (tetragonal), 4 (tetragonal), and mm2 (orthorhombic). In preferred embodiments the polar perovskite compound may be a compound with a crystallographic point group selected from 4 mm (tetragonal), 4 (tetragonal), 3 m (trigonal), 3 (trigonal), and mm2 (orthorhombic).

In some embodiments, the polar perovskite compound is capable of forming a ceramic material comprising a major portion of a tetragonal phase having an axial ratio c/a of between 1.005 and 1.04, preferably from 1.01 to 1.02, or where the polar perovskite compound is capable of forming a ceramic material comprising a major portion of a rhombohedral phase having a rhombohedral angle of 89.5 to 89.9 degrees and a crystallographic point group symmetry which is 3 m or 3.

Computer modelling may be used to aid in evaluating the crystallographic properties of a solid solution of a combination of perovskite compounds over different molar ratios of the compounds, if desired. The skilled person is familiar with a number of open-source software packages that may be of use in this regard. For example, use may be made of molecular dynamics simulator software, such as the large-scale atomic/molecular massively parallel simulator (LAMMPS) from Sandia National Laboratories, in order to predict stability of solid solutions of different crystalline components. Alternatively or additionally, use may also be made of density functional theory (DFT) software, such as OpenMX.

The solid solution ceramic materials obtained as described above may exhibit a phase stability over a large range of temperature (i.e. no temperature induced phase transition occurring over a large range of temperature). The ceramic materials may also undergo the field induced phase transition discussed herein over a large range of temperature. In preferred embodiments, said solid solution ceramic materials exhibit phase stability and are active for a field induced phase transition in accordance with the invention over a temperature range of from −50° C. to 200° C., more preferably from −5° C. to 150° C., still more preferably from 0° C. to 100° C.

The term “perovskite compound” used herein may be represented by “ABX₃”, where ‘A’ and ‘B’ are cations of different sizes, and X is an anion that bonds to both cations. As the skilled person is aware, the perovskite structure itself has the ‘A’ and ‘B’ cations arranged at particular sites, namely the A- and B-sites of the perovskite structure, respectively. As is evident herein, in order to manipulate the symmetry exhibited by a perovskite ceramic material, different perovskite compounds may be combined in a solid solution.

The term “solid solution” used herein refers to a mixture of two or more crystalline solids that combine to form a new crystalline solid, or crystal lattice, that is composed of a combination of the elements of the constituent compounds. As will be appreciated, the solid solution ceramic materials referred to herein may consist essentially of its constituent crystalline compounds as well as dopants and inevitable impurities. The solid solution exists over a partial or complete range of proportions or mole ratios of the constituent compounds, where at least one of the constituent compounds may be considered to be the “solvent” phase.

The term “dopant” used herein refers to a metallic or metal oxide component which may be dissolved in the solid solution of the ceramic materials of the invention in order to modify performance or engineering characteristics of the ceramic material, without having any material impact on the overall phase and symmetry characteristics of the solid solution. For instance, dopants may be used to modify grain size and domain mobility, or to improve resistivity (e.g. by compensating for excess charge carriers), temperature dependence and fatigue properties.

Examples of suitable dopants include materials comprising a metallic cation, preferably selected from Mn, Mg, Nb and Ca, for example MnO₂, MgO, Nb₂O₅ and CaO. Preferably the solid solution ceramic materials of the invention contain less than 5 wt. %, preferably less than 2 wt. %, more preferably less than 0.5 wt. % of dopant. In other preferred embodiments, the solid solution ceramic materials of the invention contain no dopant.

In some embodiments of the invention the solid solution ceramic material prepared in steps i) and iii) comprises from 30 to 50 mol. %, preferably from 35 to 45 mol. %, more preferably from 40 to 45 mol. % of the at least one polar perovskite compound and/or from 50 to 70 mol. %, preferably 55 to 65 mol. %, more preferably from 55 to 60 mol. % of the at least one non-polar perovskite compound.

The at least one polar perovskite compound employed in the solid solution ceramic materials as part of the present invention may, in some embodiments, comprise a tetragonal perovskite compound and/or a rhombohedral perovskite compound and the at least one non-polar perovskite compound comprises a cubic perovskite compound. In some embodiments the at least one polar perovskite compound is a tetragonal perovskite compound comprising a metal cation selected from Ti⁴⁺, Zr⁴⁺, Nb⁵⁺ and Ta⁵⁺, preferably in the B-site of the perovskite structure. Additionally or alternatively, the tetragonal perovskite compound may comprise a metal cation which is Ba²⁺ or a pair of charge compensated metal cations which is Bi³⁺_{0.5}K⁺_{0.5}, or Bi³⁺_{0.5}Na⁺_{0.5}, or Bi³⁺_{0.5}Li⁺_{0.5}, preferably in the A-site of the perovskite structure. The tetragonal perovskite compound may be selected, for example, from (Bi_{0.5}K_{0.5})TiO₃, BaTiO₃, or even PbTiO₃ since lead-lean ceramic materials are also of interest.

The solid solution may comprise at least one non-polar cubic perovskite compound. In preferred embodiments, the solid solution comprises at least two non-polar cubic perovskite compounds. In some embodiments one of the non-polar perovskite compound may be selected from (Bi_{0.5}Na_{0.5})TiO₃ and SrTiO₃.

In other embodiments, the at least one non-polar perovskite compound may have a metal cation component with a filled valence electron shell, such as a metal cation selected from Sr²⁺, Ba²⁺ and Ca²⁺. In preferred embodiments said metal cation is in the A-site of the perovskite structure.

Additionally or alternatively said non polar perovskite compound may have a metal cation component with a non-filled valence electron shell, preferably selected from Sn⁴⁺, In³⁺, Ga³⁺ Zn²⁺, and Ni²⁺. In preferred embodiments, the metal cation is in the B-site of the perovskite structure.

In further embodiments the at least one non-polar perovskite compound comprises a metal cation selected from Sr²⁺, Ba²⁺ and Ca²⁺. It is preferred that said cation is located on the A-site of the perovskite structure. Additionally or alternatively, the at least one non-polar perovskite compound comprises a metal cation selected from Hf⁴⁺ and Zr⁴⁺, preferably on the B-site of the perovskite structure. In more preferred embodiments, the at least one non-polar perovskite compound is SrHfO₃ and/or SrZrO₃.

The disruption of the long range order of the parent phase can be better achieved where the compound of the non polar perovskite is chemically dissimilar to the compound of the polar perovskite, in addition to exhibiting different symmetry. Thus, the compound or compounds of the non-polar and of the polar perovskites are preferably selected to be chemically dissimilar in order to enhance the benefits in terms of the properties of the resulting solid solution ceramic material.

Such chemical differences may be derived from differences in electronic structure, as well as valence, size and electronegativity of the ions of the perovskite compounds, which differences may be described by certain parameters, for example effective ionic charge, Shannon-Prewitt effective ionic radius, and Pauling electronegativity value. In selecting polar and non-polar perovskite compounds for use in the present invention, it is preferred that the metal cations occupying the A- and/or B-site in the polar and non-polar perovskite compounds are different. By selecting perovskite compounds based on these differences, selection of perovskite constituent compounds for use in the solid solution ceramic materials of the invention may be facilitated.

In some embodiments, the solid solution may include at least one polar perovskite compound which has a metal cation occupying the A- and/or B-site of the perovskite structure having an effective ionic charge that differs from that of the corresponding metal cation occupying the A- and/or B-site of the at least one non-polar perovskite compound of the solid solution, preferably where the difference in effective ionic charge is from 1 to 3.

In other embodiments the solid solution may include at least one polar perovskite compound which has a metal cation occupying the A- and/or B-site of the perovskite structure having a Shannon-Prewitt effective ionic radius that differs from that of the corresponding metal cation occupying the A- and/or B-site of the at least one non-polar perovskite compound of the solid solution, preferably where the difference in Shannon-Prewitt effective ionic radius is from 5 to 25%, preferably 5 to 15%.

In further embodiments, the solid solution may include at least one polar perovskite compound which has a metal cation occupying the A- and/or B-site of the perovskite structure having an Pauling electronegativity value of the element occupying the A- and/or B-site that differs from that of the corresponding element occupying the A- and/or B-site of the at least one non-polar perovskite compound of the solid solution, preferably where there is a Pauling electronegativity value difference of from 0.2 to 1.2.

The ceramic material with an increased difference, Pₘₐₓ−Pᵣ, in maximum polarization, Pₘₐₓ, and remanent polarisation, Pᵣ, prepared in step iii)a) or step iii)b), as described above, compared to the ceramic material of step i), as described above, may have a remanent polarisation, Pᵣ, of less than 10 μC/cm²; preferably less than 5 μC/cm²; a maximum polarisation, Pₘₐₓ, of greater than 20 ρC/cm²; preferably greater than 25 μC/cm², so that the difference, Pₘₐₓ−Pᵣ, in maximum polarization, Pₘₐₓ, and remanent polarisation, Pᵣ, of the ceramic material is greater than 10 μC/cm²; preferably greater than 20 μC/cm².

Said ceramic material may also have an effective piezoelectric strain coefficient d₃₃* of from 50 to 1000 pm/V; and/or a maximum electromechanical strain value of from 0.1% to 0.5%, when measured at 1-100 Hz and at standard temperature and pressure.

In another aspect, the present invention provides a method of preparing a solid solution ceramic material including at least one polar perovskite compound and at least one non-polar perovskite compounds, said method comprising the steps of: I) mixing precursors for the perovskite compounds of the ceramic material in predetermined molar ratios; wherein the predetermined molar ratios of precursors are determined based on the molar ratio of perovskite compounds in the solid state ceramic material determined in step iii)a) according to the method as described above, and II) utilising the mixture of precursors formed in step I) in a solid-state synthesis to prepare the solid solution ceramic material. In other implementations said method may comprise the steps of: A) mixing precursors for the perovskite compounds of the ceramic material in predetermined molar ratios; wherein the predetermined molar ratios of precursors are determined based on the molar ratio of perovskite compounds in the solid state ceramic material determined in step i) described above; and B) utilising the mixture of precursors formed in step A) in a solid-state synthesis to prepare the solid solution ceramic material; wherein the processing conditions used to provide an increased difference, Pₘₐₓ−Pᵣ, in maximum polarization, Pₘₐₓ, and remanent polarisation, Pᵣ, of the solid solution determined in step iii)b) according to the method as described above are used to prepare the ceramic material.

The solid solution ceramic material of the invention may also be fabricated in the form of a thin film by any suitable deposition method. For example, atomic layer deposition (ALD), chemical vapour deposition (CVD) (including plasma-enhanced chemical vapour deposition (PECVD) and metalorganic chemical vapour deposition (MOCVD)), and chemical solution deposition (CSD) may be employed. using appropriate precursors. Examples of suitable precursors include titanium (IV) isopropoxide, titanium butoxide, bismuth acetate, bismuth nitrate, bismuth 2-ethylhexanoate, barium acetate, barium nitrate, barium 2-ethyl hexanoate, sodium acetate trihydrate, sodium nitrate, potassium acetate, potassium nitrate, magnesium acetate tetrahydrate, magnesium nitrate, zinc acetate and zinc nitrate. Suitable solvents that may be employed in these methods where appropriate include alcohols (for example, methanol, ethanol and 1-butanol) and organic acids (for example, acetic acid and propionic acid). Suitable stabilisers that may be employed in these methods where appropriate include acetylacetone and diethanolamine. Sputtering using solid state sintered or hot-pressed ceramic targets may also be employed, if desired. Such thin films may have a thickness in the range of from 0.3 μm to 5 μm, preferably in the range of from 0.5 μm to 3 μm.

Where the solid solution ceramic material is fabricated as a thin film, it will be appreciated that tensile stresses associated with the thin film can affect field-induced strains and the magnitude of the effective piezoelectric coefficient d₃₃*. The skilled person is able to determine the extent of residual tensile stresses associated with a fabricated thin film and take steps to control such stresses (for example, utilising thermal anneals to relieve stress, by designing the device architecture to achieve a desired stress state, and by adjusting process conditions to control film thickness) in order to gain the maximum benefit of the field-induced strains associated with the solid solution ceramic materials of the present invention.

As will be appreciated, this approach can also, for instance, be utilised when the solid solution ceramic material is fabricated as a thin film forming part of an actuator component of a droplet deposition apparatus, described in further detail below. The skilled person is able to accommodate for, or mitigate, intrinsic stresses resulting from the configuration of the actuator component so as to ensure that the reversible phase transition associated with the ceramic material of the invention is possible in response to an electric field. Thus, as applied to the droplet deposition apparatus, the skilled person is able to ensure that the gain or loss of strain resulting from the reversible phase change caused by the application of an ejection waveform to an actuator element formed of the ceramic material is sufficient to cause ejection of a droplet. In one example, this might be accomplished by appropriate design of the ejection waveform. This may, for instance, include identifying a suitable amplitude for the ejection waveform (e.g. suitable peak-to-peak amplitude) and/or identifying suitable maximum and minimum voltage values (with the characteristic phase transition occurring upon change between maximum and minimum voltage values). The thus-designed ejection waveform may accommodate for, or mitigate, the effect that intrinsic stresses has on the conditions necessary to elicit the reversible phase transition.

In accordance with a further aspect, the present invention also provides a method of reversibly converting a ceramic material obtained through the method as described hereinabove into a ceramic material comprising a major proportion of a polar state, said method comprising the step of applying an electric field to said ceramic material.

Ceramic materials prepared in accordance with the method of the present invention may be employed as actuating elements in a variety of actuator components. For instance, such an actuator component may find use in a droplet deposition apparatus. Droplet deposition apparatuses have widespread usage in both traditional printing applications, such as inkjet printing, as well as in 3D printing and other materials deposition or rapid prototyping techniques.

Thus, in accordance with another aspect, the present invention also provides an actuator component for use in a droplet ejection apparatus comprising a ceramic material prepared by the method of the present invention as described hereinabove. Accordingly, in a related aspect, there is also provided a method of actuating the actuator component, said method comprising the step of applying an electric field to the actuator component. In another related aspect, there is provided a droplet deposition apparatus comprising the actuator component.

An actuator component suitable for use in a droplet deposition apparatus may, for instance, comprise a plurality of fluid chambers, which may be arranged in one or more rows, each chamber being provided with a respective actuator element and a nozzle. The actuating element is actuatable to cause the ejection of fluid from a chamber of the plurality through a corresponding one of the nozzles. The actuating element is typically provided with at least first and second actuation electrodes configured to apply an electric field to the actuating element, which is thereby deformed, thus causing droplet ejection. Additional layers may also be present, including insulating, semi-conducting, conducting, and/or passivation layers. Such layers may be provided using any suitable fabrication technique such as, for example, a deposition/machining technique, e.g. sputtering, CVD, PECVD, MOCVD, ALD, laser ablation etc. Furthermore, any suitable patterning technique may be used as required, such as photolithographic techniques (e.g. providing a mask during sputtering and/or etching).

The actuating element may, for example, function by deforming a wall bounding one of the fluid chambers of the actuator component. Such deformation may in turn increase the pressure of the fluid within the chamber and thereby cause the ejection of droplets of fluid from the nozzle. Such a wall may be in the form of a membrane layer which may comprise any suitable material, such as, for example, a metal, an alloy, a dielectric material and/or a semiconductor material. Examples of suitable materials include silicon nitride (Si₃N₄), silicon oxide (SiO₂), aluminium oxide (Al₂O₃), titanium oxide (TiO₂), silicon (Si) or silicon carbide (SiC). The actuating element may include the ceramic material described herein in the form of a thin film. Such thin films may be fabricated, including in multiple layers, using different techniques well known to the skilled person, including sputtering, sol-gel, chemical solution deposition (CSD), aerosol deposition and pulsed laser deposition techniques.

The droplet deposition apparatus typically comprises a droplet deposition head comprising the actuator component and one or more manifold components that are attached to the actuator component. Such droplet deposition heads may, in addition, or instead, include drive circuitry that is electrically connected to the actuating elements, for example by means of electrical traces provided by the actuator component. Such drive circuitry may supply drive voltage signals to the actuating elements that cause the ejection of droplets from a selected group of fluid chambers, with the selected group changing with changes in input data received by the head.

To meet the material needs of diverse applications, a wide variety of alternative fluids may be deposited by droplet deposition heads as described herein. For instance, a droplet deposition head may eject droplets of ink that may travel to a sheet of paper or card, or to other receiving media, such as textile or foil or shaped articles (e.g. cans, bottles etc.), to form an image, as is the case in inkjet printing applications, where the droplet deposition head may be an inkjet printhead or, more particularly, a drop-on-demand inkjet printhead.

Alternatively, droplets of fluid may be used to build structures, for example electrically active fluids may be deposited onto receiving media such as a circuit board so as to enable prototyping of electrical devices. In another example, polymer containing fluids or molten polymer may be deposited in successive layers so as to produce a prototype model of an object (as in 3D printing). In still other applications, droplet deposition heads might be adapted to deposit droplets of solution containing biological or chemical material onto a receiving medium such as a microarray.

Droplet deposition heads suitable for such alternative fluids may be generally similar in construction to printheads, with some adaptations made to handle the specific fluid in question. Droplet deposition heads which may be employed include drop-on-demand droplet deposition heads. In such heads, the pattern of droplets ejected varies in dependence upon the input data provided to the head.

The present invention will now be described by reference to the following Examples which are intended to be illustrative of the invention and in no way limiting.

### EXAMPLES

General Method for the Preparation of Ceramic Materials

Appropriate amounts of Bi₂O₃, TiO₂, Na₂CO₃, KCO₃, SrCO₃, ZrO₂, and HfO₂ starting powders of at least 99% purity were utilised to make ceramic materials of a solid solution of BNT-BKT or a ceramic material according to formula (I).

xBNT-yBKT-zABO₃ (I)

(where ABO₃ is a further perovskite component as described previously)

Mixtures were prepared consisting of ethanol and the ceramics powders, where the concentration of ceramic powder was approximately 15 vol. %. For the milling step, high density yttria stabilised zirconia (YSZ) beads of approximately ⅜ inch (0.95 cm) diameter were added to the mixture. The milling was conducted by means of high energy vibratory milling for a period of two to six hours. The YSZ beads were removed by means of a sieving device, the powders were dried in an evaporation oven, and the dry powders were calcined in alumina or magnesia crucibles at approximately 800-950° C. for 6 hours. An additional milling step was performed for post-calcination grinding of the powders from two to six hours following a similar procedure as described above.

The calcined powders were subsequently mixed with a 3 wt. % solution of polymer binder, (e.g. polyvinyl butyral (PVB)), and the powders were uniaxially cold pressed into 12.7 mm pellets at a pressure of 150 MPa in a Carver press. Following a 400° C. binder burnout step, the pellets/discs were sintered in covered crucibles at 1000-1200° C. from 0.5 to 8 hours. The ceramic discs were polished to thickness of approximately 0.9 mm with smooth and parallel surfaces.

The ceramic materials were prepared in a systematic manner such that the mole fraction of the further perovskite component (ABO₃) according to formula (I), and/or a processing parameter (calcination, sintering temperature, sintering time or atmosphere), and/or the addition of defects was varied. Measurements of the parameter Pₘₐₓ−Pᵣ were conducted on the materials for each group and those with the largest Pₘₐₓ−Pᵣ parameter were identified as those with the optimum d₃₃* value.

The skilled person is able to utilise known measurement techniques for assessing strain and polarization, in order to modify the short range order exhibited in a solid solution ceramic material. For instance, this may be readily achieved by adjusting compositional characteristics, such the particular ratio of perovskite compounds of the solid solution and/or an amount of, for example, an optional ternary phase (additional perovskite compound). Alternatively or additionally, defects may be introduced into the solid solution ceramic material to disrupt short range order, for example by intentionally introducing non-stoichiometry in the processing conditions, or through control of processing times and temperatures which generate defects due to cation volatility. Disruption of the short range order in this manner allows the skilled person to provide a solid solution ceramic material modified to be close to the ergodic to non-ergodic boundary for a given operating temperature (such as room temperature), where a non-polar to polar state change is possible on the application of an electric field.

General Methods for Application of Electrodes to the Prepared Ceramic Materials

In a first method, silver paste (Heraeus C1000) was fired on both sides in air at 650° C. for 30 minutes.

In a second method, thin film electrodes of an inert metal such as Au, Ag, or Pt or the ceramic indium tin oxide (ITO) were applied to both sides of the specimen using DC magnetron sputtering in vacuum using standard methods.

Analyses Carried Out on the Materials

X-ray diffraction analysis was completed for the ceramic materials prepared, according to the method detailed above, using Cu Kα radiation (Bruker AXS D8 Discover, Madison, Wis., USA) on ground pellets and analysed for phase and crystal structure determination.

The polarisation hysteresis behaviour of ceramic materials were measured after the preparation of electrodes in accordance with the general methods set out above. Polarisation was measured at 10 Hz at room temperature using an AixACCT Piezoelectric Characterization System. Values of the parameter Pₘₐₓ−Pᵣ were obtained from polarisation hysteresis measurements using a Sawyer-Tower circuit.

The electromechanical strain responses for ceramic materials were measured after the preparation of electrodes in accordance with the general methods set out above. Electromechanical strain response was measured at 10 Hz at room temperature using an AixACCT Piezoelectric Characterization System fitted with an interferometer.

### Example 1

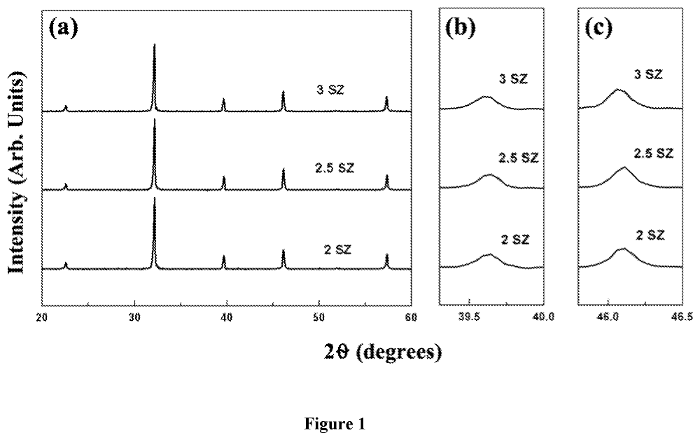

XRD data shown in FIG. 1 are related to three ceramic materials with similar compositions including BNT-BKT as a polar perovskite to which SrZrO₃ (SZ), as a non-polar perovskite, was added in different amounts (2 mol. %, 2.5 mol. %, and 3 mol. %). All materials are indexed to a cubic perovskite unit cell.

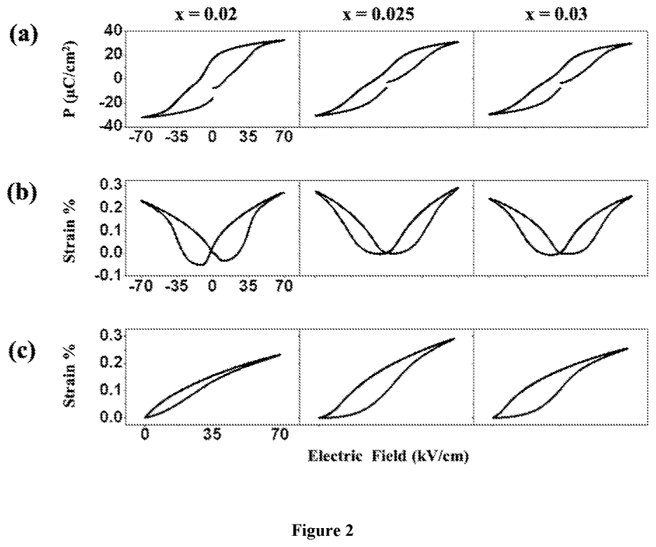

However, the polarisation hysteresis and electromechanical behaviour of these ceramic material show that the stability of the polarization changes significantly over this span of compositions. The polarisation-electric field data shown in FIG. 2a demonstrates that the polarization is stable at 2% SZ, however with increased SZ content the remanent polarization decreases to nearly zero and as a consequence the field induced strain is maximum at 2.5% SZ as seen in FIGS. 2b and 2c. Furthermore, crystal structures are determined at zero field, which does not give a true representation of the polarised material when under non-zero field. Thus, a dramatic change in the electromechanical properties occurs over a range of compositions which otherwise appear to be identical from a crystal structure standpoint (as shown in FIG. 1), as defined by the long-range average crystal structure determined from x-ray diffraction measurements. This demonstrates the importance of the short range order, in addition to the long-range crystal structure, in providing compositions with enhanced d₃₃*.

### Example 2

Composition can be used to control the stability of the polarization. The introduction of a “disorder phase” into the parent phase creates a disruption in the long-range order of the perovskite structure. At the same time, the introduction of dissimilar cations into the perovskite lattice acts to destabilise the polarisation through the disruption of short-range order.

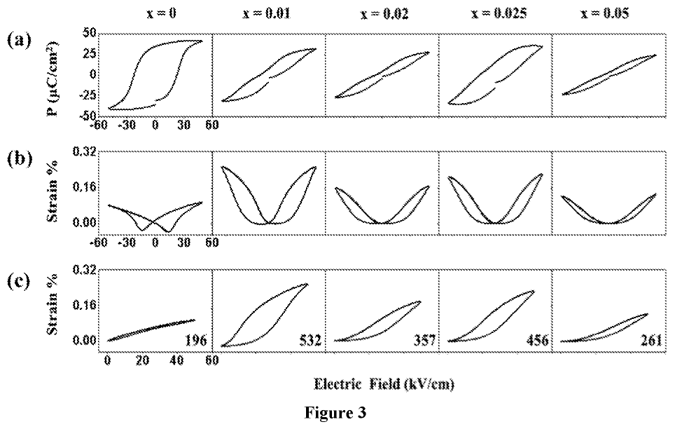

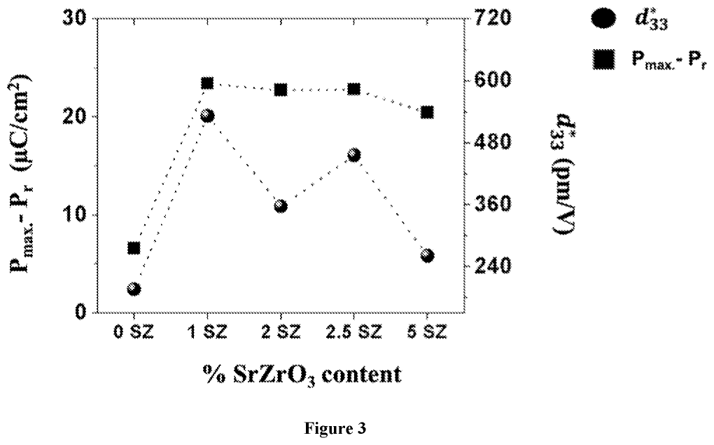

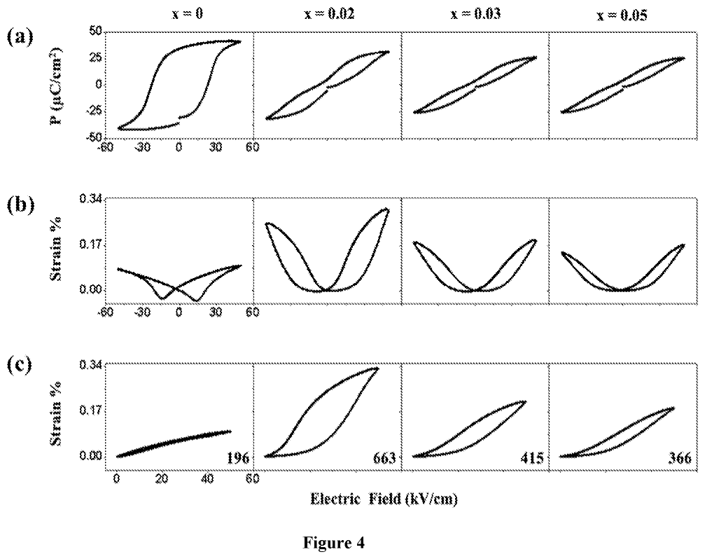

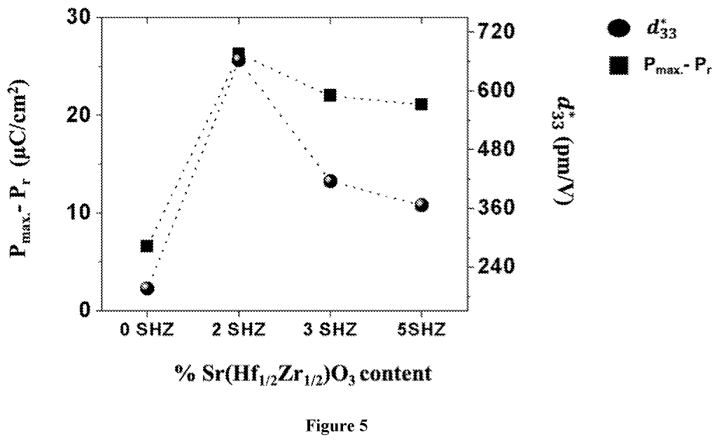

The data in FIGS. 3 and 5 show the addition of SrZrO₃ (SZ) and Sr(Hf_{1/2}Zr_{1/2})O₃ (SHZ) respectively to the BNT-BKT lattice. The introduction of SZ and SHZ destabilises the polarisation as seen by a decrease in the remanent polarisation. Maximum values of the d₃₃* are found after a shift in the Pₘₐₓ−Pᵣ parameter (at 1% SZ and 2% SHZ as shown in the FIGS. 4 and 6, respectively).

### Example 3

The processing conditions, for example sintering time, temperature, atmosphere and pressure, can be used to control the stability of the polarisation and hence the electromechanical properties. The mechanism behind this phenomenon is linked to changes in the material that occur during the high temperature sintering process. For example, BNT-BKT-SZ-based materials include a number of volatile cations (e.g. Na, K, Bi) and thus the stoichiometry changes as a function of time through loss of those volatile cations. Furthermore, there may be changes in crystallite size and homogeneity of the material after extended time at those temperatures.

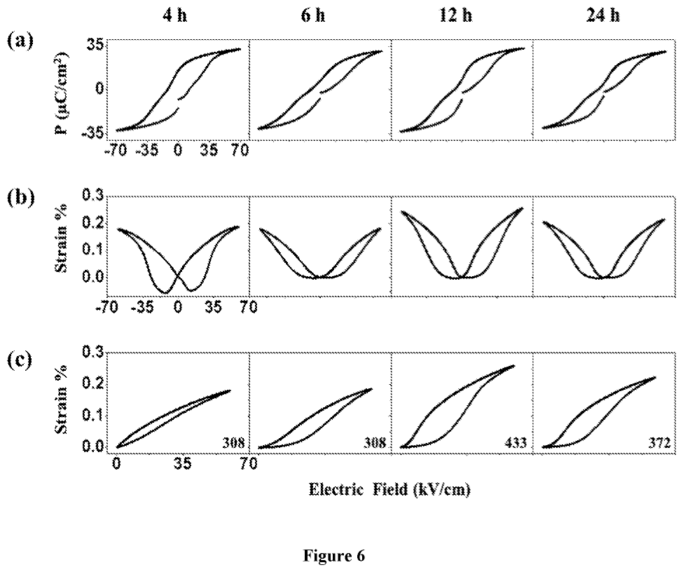

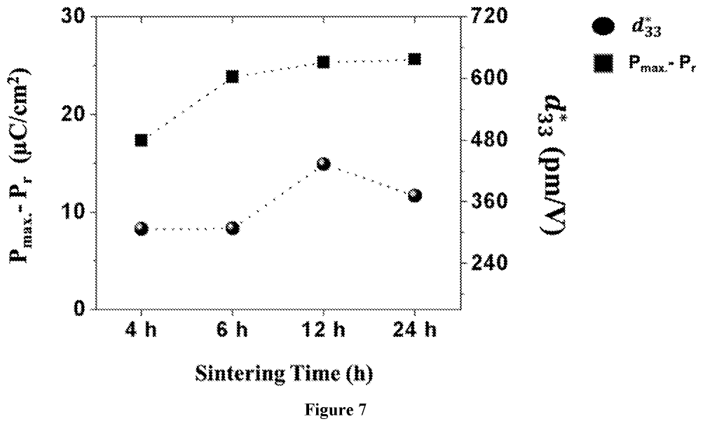

The data of FIGS. 7 and 8 show a clear shift in the stability of the polarization at different sintering times. As the remanent polarization decreases there is an increase in the overall field induced strain (d₃₃*).

### Example 4

The introduction of non-stoichiometric amounts of cations (for example Na⁺ and K⁺) can also be used to control the stability of the polarization and hence the electromechanical properties. The mechanism behind this phenomenon is similar to the effects of composition and sintering time, as it is linked to changes in the material that occur during the high temperature sintering process. Manipulation of the concentration of volatile cations (e.g. Na, K, Bi) and thus the overall stoichiometry impacts the stability of the polarization. Furthermore, the concentration of volatile cations may impact the crystallite size and homogeneity of the material which in turn may affect the electromechanical properties.

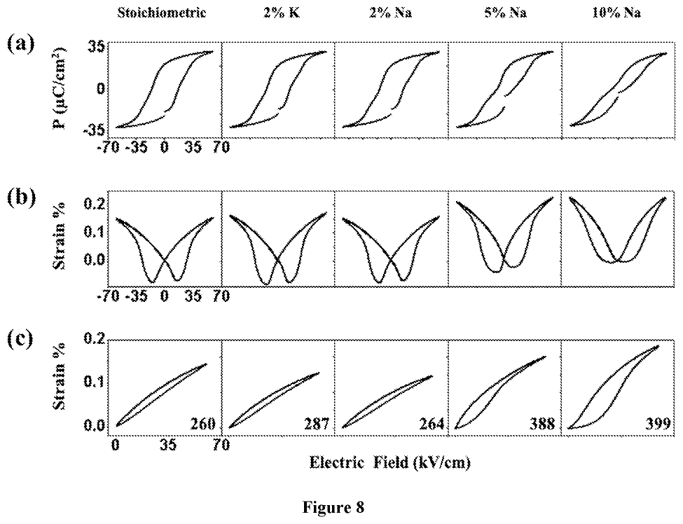

The data of FIG. 9 show a clear shift in the stability of the polarization as a function of the concentration of volatile cations Na⁺ and K⁺. As the remanent polarization decreases there is a clear increase in the overall field induced strain (d₃₃*).

It will be understood that more than one of the parameters described above (for example, composition, processing conditions, and introduction of cation non-stoichiometric excess or deficiency) may be optimised at the same time.

1. A method of increasing electromechanical strain in a solid solution ceramic material which exhibits an electric field induced strain derived from a reversible transition from a non-polar state to a polar state, the method comprising;
i) determining a molar ratio of at least one polar perovskite compound having a polar crystallographic point group to at least one non-polar perovskite compound having a non-polar crystallographic point group which, when combined to form a solid solution, forms a ceramic material with a major portion of a non-polar state;
ii) determining the maximum polarization, Pmax, remanent polarization, Pr, and the difference, Pmax−Pr, for the solid solution formed in step i); and either:
iii)a) modifying the molar ratio determined in step i) to form a different solid solution of the same perovskite compounds which exhibits an electric field induced strain and which has a greater difference, Pmax−Pr, between maximum polarization, Pmax, and remanent polarization, Pr, than for the solid solution from step i), or;
iii)b) adjusting the processing conditions used for preparing the solid solution formed in step i) to increase the difference, Pmax−Pr, in maximum polarization, Pmax, and remanent polarization, Pr, of the solid solution;
wherein the solid solution formed in step i) comprises at least one non-polar cubic perovskite compound comprising: a) at least one metal cation selected from Sr²⁺, Ba²⁺ and Ca²⁺; and b) a Hf⁴⁺ metal cation; and
wherein the solid solution formed in step i) further comprises at least one of:
1) a polar tetragonal perovskite compound selected from (Bi_{0.5}K_{0.5})TiO₃ and BaTiO₃; and
2) a non-polar cubic perovskite compound selected from (Bi_{0.5}Na_{0.5})TiO₃ and SrTiO₃.

2. The method according to claim 1, wherein step i) comprises the following sub-steps:
i-a) preparing at least one solid solution ceramic material of at least one polar perovskite compound and at least one non-polar perovskite compound, including the non-polar cubic perovskite compound comprising: a) at least one metal cation selected from Sr²⁺, Ba²⁺ and Ca²⁺; and b) a Hf⁴⁺ metal cation, in a particular molar ratio;
i-b) determining whether at least one of the axial ratio c/a and rhombohedral angle of a major phase of the at least one solid solution ceramic material prepared in step i-a) corresponds to a pseudo-cubic phase having at least one of an axial ratio c/a of from 0.995 to 1.005 and a rhombohedral angle of 90±0.2 degrees;
i-c) optionally repeating sub-steps i-a) and i-b) using a different molar ratio of the at least one polar perovskite compound and the at least one non-polar perovskite compound, including the non-polar cubic perovskite compound comprising: a) a metal cation selected from Sr²⁺, Ba²⁺ and Ca²⁺; and b) a Hf⁴⁺ metal cation, to that of step i-a) until at least one of the axial ratio c/a and rhombohedral angle of a major phase of the resulting solid solution ceramic material corresponds to a pseudo-cubic phase having at least one of an axial ratio c/a of from 0.995 to 1.005 and a rhombohedral angle of 90±0.2 degrees.

3. The method according to claim 1, wherein step iii)a) comprises the following sub-steps:
iii)a)-1 preparing at least one solid solution ceramic material comprising the same perovskite compounds of step i) in a different molar ratio; wherein the solid solution prepared has a major portion of a non-polar state in the absence of an applied electric field and a major portion of a polar state in the presence of an applied electric field;
iii)a)-2 determining whether the difference, Pmax−Pr, between maximum polarization, Pmax, and remanent polarization, Pr, for the at least one solid solution prepared in sub-step iii)a-1 is greater than that of the solid solution from step i);
iii)a)-3 optionally repeating sub-steps iii)a)-1 and iii)a)-2 using a different molar ratio of the perovskite compounds to that of step iii)a)-1 until the difference, Pmax−Pr, between maximum polarization, Pmax, and remanent polarization, Pr, for the solid solution is greater than that for the solid solution prepared in step i).

4. The method according to claim 1, wherein step iii)b) comprises at least one of: 1) changing at least one of the calcination and sintering temperature of a solid state synthesis; 2) changing at least one of the calcination and sintering time of a solid state synthesis; and 3) changing at least one of the cationic excess or deficiency of constituent cations in a solid state or solution phase synthesis, used in the preparation of the solid solution until the difference, Pmax−Pr, between maximum polarization, Pmax, and remanent polarization, Pr, is greater than that for the solid solution prepared in step i).

5. The method according to claim 4, wherein in step i) the solid solution is prepared by a solid state synthesis which includes from 1 to 12 hours of a sintering step and where step iii)b) comprises increasing the sintering time by from 50 to 1000%.

6. The method according to claim 4, wherein in step i) the solid solution is prepared by a solid state synthesis which includes a sintering step performed at from 900 to 1400° C. and where step iii)b) comprises increasing the sintering temperature by 5 to 25%.

7. The method according to claim 1, wherein the solid solutions prepared in steps i) and iii) comprise at least one of a single polar perovskite compound and a plurality of non-polar perovskite compounds, including the non-polar cubic perovskite compound comprising: a) a metal cation selected from Sr²⁺, Ba²⁺ and Ca²⁺; and b) a Hf⁴⁺ metal cation.

8. The method according to claim 1, wherein the at least one polar perovskite compound is selected from compounds with a crystallographic point group selected from 6 mm (hexagonal), 6 (hexagonal), 4 mm (tetragonal), 4 (tetragonal), 3 m (trigonal), 3 (trigonal), mm2 (orthorhombic), 2 (monoclinic), m (monoclinic), and 1 (triclinic).

9. The method according to claim 1, wherein the polar perovskite compound is capable of forming at least one of:
a ceramic material comprising a major portion of a tetragonal phase having an axial ratio c/a of between 1.005 and 1.04, or
a ceramic material comprising a major portion of a rhombohedral phase having a rhombohedral angle of 89.5 to 89.9 degrees and a crystallographic point group symmetry which is 3 m or 3.

10. (canceled)

11. The method according to claim 1, wherein the solid solution ceramic material prepared in steps i) and iii) comprises at least one of:
from 30 to 50 mol. % of the at least one polar perovskite compound; and
from 50 to 70 mol. % of the at least one non-polar perovskite compound.

12. The method according to claim 1, wherein the at least one polar perovskite compound comprises a tetragonal perovskite compound comprising at least one metal cation selected from Ti⁴⁺, Zr⁴⁺, Nb⁵⁺ and Ta⁵⁺.

13. The method according to claim 1, wherein the at least one polar perovskite compound comprises a tetragonal perovskite compound comprising a cationic species which is at least one of Ba²⁺ or a pair of charge compensated metal cations which is at least one of Bi³⁺_{0.5}K¹⁺_{0.5}, Bi³⁺_{0.5}Na⁺_{0.5}, or Bi³⁺_{0.5}Li⁺_{0.5}.

14. (canceled)

15. (canceled)

16. (canceled)

17. (canceled)

18. The method according to claim 1, wherein the solid solution includes at least one of:
i) a polar perovskite compound which has a metal cation occupying at least one of the A- and B-site of the perovskite structure having an effective ionic charge that differs from that of the corresponding metal cation of the at least one non-polar perovskite compound of the solid solution;
ii) a polar perovskite compound which has a metal cation occupying at least one of the A- and B-site of the perovskite structure having a Shannon-Prewitt effective ionic radius that differs from that of the corresponding metal cation of the at least one non-polar perovskite compound of the solid solution; and
iii) a polar perovskite compound which has a metal cation occupying at least one of the A- and B-site of the perovskite structure having an Pauling electronegativity value that differs from that of the corresponding element of the at least one non-polar perovskite compound of the solid solution.

19. The method according to claim 1, wherein the at least one non-polar cubic perovskite compound is SrHfO₃.

20. The method according to claim 1, wherein the ceramic material with an increased difference, Pmax−Pr, in maximum polarization, Pmax, and remanent polarization, Pr, in step iii)a) or step iii)b) compared to the ceramic material of step i) has at least one of:
a) a remanent polarization, Pr, of less than <10 μC/cm²;
b) a maximum polarization, Pmax, of greater than >20 μC/cm²;
c) wherein the difference, Pmax−Pr, in maximum polarization, Pmax, and remanent polarization, Pr, of the ceramic material is greater than 10 μC/cm²;
d) an effective piezoelectric strain coefficient d₃₃* of from 50 to 1000 pm/V; and
e) a maximum electromechanical strain value of from 0.1% to 0.5%, when measured at 1-100 Hz and at standard temperature and pressure.

21. The method of preparing a solid solution ceramic material of at least one polar perovskite compound and at least one non-polar perovskite compounds, as defined in claim 1, wherein the ceramic material comprises a major portion of a non-polar state in the absence of an applied electric field and a major portion of a polar state in the presence of an applied electric field; said method comprising the steps of:
I) mixing precursors for the perovskite compounds of the ceramic material in predetermined molar ratios; wherein the predetermined molar ratios of precursors are determined based on the molar ratio of perovskite compounds in the solid state ceramic material determined in step iii)a) according to claim 1; and
II) utilizing the mixture of precursors formed in step I) in a solid-state synthesis to prepare the solid solution ceramic material.

22. (canceled)

23. The solid solution ceramic material of at least one polar perovskite compound and at least one non-polar perovskite compound as defined in claim 1, wherein the ceramic material comprises a major portion of a non-polar state in the absence of an applied electric field and a major portion of a polar state in the presence of an applied electric field; wherein the difference, Pmax−Pr, in maximum polarization, Pmax, and remanent polarization, Pr, of the ceramic material is greater than 30 μC/cm².

24. An actuator component for use in a droplet ejection apparatus comprising a ceramic material as defined in claim 23.

25. A droplet ejection apparatus comprising an actuator component as defined in claim 24.

26. A method of preparing a solid solution ceramic material of at least one polar perovskite compound and at least one non-polar perovskite compounds, as defined in claim 1, wherein the ceramic material comprises a major portion of a non-polar state in the absence of an applied electric field and a major portion of a polar state in the presence of an applied electric field; said method comprising the steps of:
A) mixing precursors for the perovskite compounds of the ceramic material in predetermined molar ratios; wherein the predetermined molar ratios of precursors are determined based on the molar ratio of perovskite compounds in the solid state ceramic material determined in step i) according to claim 1; and
B) utilizing the mixture of precursors formed in step A) in a solid-state synthesis to prepare the solid solution ceramic material; wherein the processing conditions used to provide an increased difference, Pmax−Pr, in maximum polarization, Pmax, and remanent polarization, Pr, of the solid solution determined in step iii)b) according to claim 1 are used to prepare the ceramic material.
